(19) United States
(12) Patent Application Publication
(10) Pub. No.: US 2014/0077233 A1
(43) Pub. Date: Mar. 20, 2014

(54) Input output LED apparatus

(71) Applicant: Khok Hing-Wai, Tseun Wan (HK)

(72) Inventor: Khok Hing-Wai, Tseun Wan (HK)

(73) Assignee: Khok Hing-Wai, Tseun Wan (CN)

(21) Appl. No.: 13/573,505

(22) Filed: Sep. 19, 2012

(51) Int. Cl. H01L 27/15; H01L 27/14; H01L 31/12

(52) U.S. Cl. 257/82; 257/88; 257/433; 257/E31.095; 257/E27.12; 257/E27.122

(57) ABSTRACT

A multi-functional optoelectronic apparatus which comprises an integrated circuit (IC) wafer, respective optoelectronic components which has one or more Input port(s) to receive external command signals to drive the optoelectronic apparatus. Examples of some of the optoelectronic apparatus include an IOLED (Input/Output Light Emitting Diode including visible light and invisible light), IOPD (Input/Output Photo Diode), IOPT (Input/Output Photo Transistor), IOLS (Input/Output Light Sensor), IORS (Input/Output Reflective Sensor), IOPI (Input/Output Photo Interrupter) and IORM (Input/Output Receiver Module). The multi-functional optoelectronic apparatus may drive external peripheral(s) such as speakers, motors or other devices. This invention eliminates the need for Printed Circuit Boards for holding the IC and remove the need for unnecessary encapsulation materials, and may be structured as Pin Packaging having three or more supporting legs and/or SMD (Surface Mount Device) Packaging having no supporting leg but having three or more connecting pads. The invention also employs double bonding agents for affixing and operatively coupling the IC wafer.

### FIELD OF INVENTION

The present disclosure relates generally to light emitting diodes (LED's) and, more particularly, to multifunctional LED and other optoelectronic devices with input and output functions.

### BACKGROUND

Light-emitting diodes (LED) may have a basic structure comprising a few components such as a light-emitting wafer which can emit visible light (such as Red, Orange, Yellow, Green, Blue, and Violet, i.e., the full spectrum of visible light and its combination and/or emit invisible light such as infrared or ultraviolet), and comprise some sort of structural housing, bonding agent (such as glue), and conductive coupling wires (such as gold, aluminum, copper, silver, or other alloy). Bonding agents may be used as a silver epoxy or silicone epoxy, and one or more light-emitting wafer may be bonded together and coupled via conductive wires. The epoxies may form a head of some sort of resin, and may take on different encapsulation shapes, which generate different illumination appearances and different spotlighting effects.

FIG. 1 illustrates a simple LED structure 50 known in the prior art. The LED structure 50 shows a basic structure of an LED comprising a light-emitting wafer 1, a lead frame 2, bonding agent 3 and a coupling wire 4. The lead frame 2 is coated with the bonding agent 3. One or more wafers 1 are affixed via the bonding agent 3, and the coupling wire 4 is connected to the lead frame 2 to provide an electrical current flow. An epoxy resin 5, or other insulation glue, is used for encapsulating the lead frame 2 within the circuit.

### Photo Diodes

Photo Diodes (PD) may have a basic structure comprising a few components such as a photo diode wafer, which can receive visible light (such as Red, Orange, Yellow, Green, Blue, and Violet, i.e., the full spectrum of visible light and its combination and/or receive invisible light such as infrared or ultraviolet), and convert the light power to electric current, some sort of structural housing, bonding agent (such as glue), and conductive coupling wires (such as gold, aluminum, copper, silver, or other alloy). Bonding agents may be used as a silver epoxy or silicone epoxy, and one or more photo diode wafer may be bonded together and coupled via conductive wires. The epoxies may form a head of some sort of resin, and may take on different encapsulation shapes, which generate different light-receiving effects. The PD structure is similar to LED as illustrated in FIG. 1 and the light-emitting wafer 1 is replaced by photo diode wafer 1.

### Photo Transistors

Photo Transistors (PT) may have a basic structure comprising a few components such as a photo transistor wafer which can receive visible light (such as Red, Orange, Yellow, Green, Blue, and Violet, i.e., the full spectrum of visible light and its combination and/or receive invisible light such as infrared or ultraviolet), and convert the light power to electric current and amplify it, some sort of structural housing, bonding agent (such as glue), and conductive coupling wires (such as gold, aluminum, copper, silver, or other alloy). Bonding agents may be used as a silver epoxy or silicone epoxy, and one or more photo transistor wafer may be bonded together and coupled via conductive wires. The epoxies may form a head of some sort of resin, and may take on different encapsulation shapes, which generate different light-receiving effects. The PT structure is similar to LED as illustrated in FIG. 1 and the light-emitting wafer 1 is replaced by photo transistor wafer 1.

### Light Sensors

Light Sensor (LS) may have a basic structure comprising a few components such as a light sensor wafer which can receive visible light (such as Red, Orange, Yellow, Green, Blue, and Violet, i.e., the full spectrum of visible light and its combination and/or receive invisible light such as infrared or ultraviolet), and convert the light power to electric current and amplify it and convert it to digital output and/or linear analog output, some sort of structural housing, bonding agent (such as glue), and conductive coupling wires (such as gold, aluminum, copper, silver, or other alloy). Bonding agents may be used as a silver epoxy or silicone epoxy, and one or more light sensor wafer may be bonded together and coupled via conductive wires. The epoxies may form a head of some sort of resin, and may take on different encapsulation shapes, which generate different light-receiving effects. The LS structure is similar to LED as illustrated in FIG. 1 and the light-emitting wafer 1 is replaced by light sensor wafer 1.

### Reflective Sensors

Reflective Sensors (RS) may have a basic structure comprising a few components such as a pair of light-emitting diode wafer which can emit visible light (such as Red, Orange, Yellow, Green, Blue, and Violet, i.e., the full spectrum of visible light and its combination and/or receive invisible light such as infrared or ultraviolet), and a photo diode wafer or a photo transistor wafer or a light sensor wafer which can receive visible light (such as Red, Orange, Yellow, Green, Blue, and Violet, i.e., the full spectrum of visible light and its combination and/or receive invisible light such as infrared or ultraviolet), some sort of structural housing, bonding agent (such as glue), and conductive coupling wires (such as gold, aluminum, copper, silver, or other alloy). Bonding agents may be used as a silver epoxy or silicone epoxy, and one or more light-emitting wafer, photo diode wafer, photo transistor wafer and/or light sensor wafer may be bonded together and coupled via conductive wires. The epoxies may form a head of some sort of resin, and may take on different encapsulation shapes, which generate different light-emitting and light-receiving effects.

FIG. 2 illustrates a simple RS structure 60 known in the prior art. The RS structure 60 shows a basic structure of an RS comprising a pair of a light-emitting wafer 11 and a photo diode wafer or photo transistor wafer or light sensor wafer 12, a lead frame 13, bonding agents 14 and a coupling wires 15. The lead frame 13 is coated with the bonding agents 14. One or more wafer 11 and wafer 12 are affixed via the bonding agents 14, and the coupling wires 15 are connected to the lead frame 13 to provide electrical current flow. An epoxy resin 16, or other insulation glue, is used for encapsulating the lead frame 13 within the circuit.

### Photo Interrupters

Photo Interrupters (PI) may have a basic structure comprising a pair of Light-emitting Diodes, and a Photo Diode or Photo Transistor or Light Sensor, and a plastic housing to hold both components. FIG. 3 illustrates a simple PI structure 70 known in the prior art. The PI structure 70 shows a basic structure of a PI comprising a light-emitting diode 21, a Photo Diode or Photo Transistor or Light Sensor 22, and a plastic housing 23.

### Receiver Modules

Receiver Modules (RM) may have a basic structure comprising a photo diode wafer which can receive visible light (such as Red, Orange, Yellow, Green, Blue, and Violet, i.e., the full spectrum of visible light and its combination and/or receive invisible light such as infrared or ultraviolet), an amplifying demodulator wafer which can amplify and demodulate the light current signal from the said photo diode wafer and output demodulated signal, some sort of structural housing, bonding agent (such as glue), and conductive coupling wires (such as gold, aluminum, copper, silver, or other alloy). Bonding agents may be used as a silver epoxy or silicone epoxy, and one or more photo diode wafer and amplifying demodulator wafer may be bonded together and coupled via conductive wires. The epoxies may form a package of some sort of resin, and may take on different encapsulation shapes, which generate different light-receiving effects. FIG. 4 illustrates a simple RM structure 80 known in the prior art. The RM structure 80 shows a basic structure of an RM comprising a photo diode wafer 31, an amplifying demodulator wafer 32, a lead frame 33, bonding agents 34 and a coupling wires 35. The lead frame 33 is coated with the bonding agents 34. One or more wafer 31 and wafer 32 are affixed via the bonding agents 34, and the coupling wires 35 are connected to the lead frame 33 to provide electrical current flow. An epoxy resin 36, or other insulation glue, is used for encapsulating the lead frame 33 within the circuit.

### Optoelectronic Devices

All the above-mentioned LED (Light-Emitting Diode), PD (Photo Diode), PT (Photo Transistor), LS (Light Sensor), RS (Reflective Sensor), PI (Photo Interrupter) and RM (Receiver Module) can be generally categorized as Optoelectronic Devices.

### Single or Multi Functional Integrated Circuits

Single or Multi Functional Integrated Circuits (IC) can receive signals, which can be trigger, on/off, or encoded signals, from Switches, PD's (Photo Diode), PT's (Photo Transistor), LS's (Light Sensor), RS's (Reflective Sensor), PI's (Photo Interrupter) or RM's (Receiver Module) and output signals to drive LEDs (Light Emitting Diode), Speakers, Motors or other electronic components.

There are several traditional structures for housing Single or Multi Functional Integrated Circuit (IC) wafers. Chip On Board (COB) is one such structure and may have a basic configuration comprising a Single or Multi Functional Integrated Circuit (IC) wafer, a printed circuit board (PCB), bonding agent (such as glue), and conductive coupling wires (such as gold, aluminum, copper, silver, or other alloy). Bonding agents may be used as a silver epoxy or silicone epoxy, and one or more IC wafer, be bonded together and coupled via conductive wires. The epoxies may form a package of some sort of resin.

FIG. 5 illustrates a simple COB structure 90 known in the prior art. The COB structure 90 shows a basic structure of a COB comprising an IC wafer 41, a printed circuit board (PCB) 42, bonding agents 43 and coupling wires 44. The PCB 42 is coated with the bonding agents 43. One or more wafers 41 are affixed via the bonding agent 43, and the coupling wires 44 are connected to the PCB 42 to provide electrical current flow. An epoxy resin 45, or other insulation glue, is used for encapsulating the wafer 41 on the PCB 42.

Encapsulated Integrated Circuit (IC) on Printed Circuit Board (PCB) is another example of housing such structures and may have a basic configuration comprising a Single or Multi Functional Integrated Circuit (IC) wafer, some sort of structural housing, bonding agent (such as glue), conductive coupling wires (such as gold, aluminum, copper, silver, or other alloy), a printed circuit board (PCB) and tin. Bonding agents may be used as a silver epoxy or silicone epoxy, and one or more IC wafer, may be bonded together and coupled via conductive wires. The epoxies may form a package of some sort of resin. The encapsulated IC may be soldered on the PCB by using tin.

FIG. 6 illustrates a simple Encapsulated IC on PCB structure 100 known in the prior art. The Encapsulated IC on PCB structure 100 shows a basic structure of a Encapsulated IC on PCB comprising an IC wafer 51, lead frame 52, bonding agents 53 and coupling wires 54, tin 55 and a printed circuit board (PCB) 56. The lead frame 52 is coated with the bonding agents 53. One or more IC wafers 51 are affixed via the bonding agent 53, and the coupling wires 54 are connected to the lead frame 52 to provide electrical current flow. An epoxy resin 57, or other insulation glue, is used for encapsulating the lead frame 52 within the circuit. Finally, the lead frame 52 is connected on the PCB 56 by soldering using tin 55.

FIG. 7 illustrates one example of a COB IC, LED and Speaker simple structure 110 known in the prior art. The COB IC 90 is connected with a switch 61, speaker 62, batteries 63 and LED 50. The COB IC 90 receives a signal from the switch 61 and outputs a signal to drive the LED 50 in a programmed pattern and outputs a signal to drive the speaker 62 to play the programmed sound.

FIG. 8 illustrates another example of a simple structure 120 known in the prior art. In this example, the COB IC 90 is connected with a Receiver Module (RM) 80, a speaker 62 and batteries 63. The COB IC 90 receives a signal from the RM 80 and output a signal to drive the speaker 62 to play the programmed sound.

The above-mentioned conventional structures are lacking in that although the required function can be achieved, the manufacturing and materials costs of such a bulky configuration are high.

Accordingly, there is a need to overcome such bulky configuration described above by a simplistic design that can be easily reproduced with readily obtainable materials, thus reducing manufacturing and materials costs.

### SUMMARY OF THE INVENTION

The present invention addresses the above-described deficiencies and others. Specifically, this invention can overcome the above bulky configuration by bonding the Single or Multi Functional Integrated Circuit (IC) into the Optoelectronic Devices including Light-Emitting Diode (LED), Photo Diode (PD), Photo Transistor (PT), Light Sensor (LS), Reflective Sensor (RS), Photo Interrupter (PI) and Receiver Module (RM) and the most important is that the invention is to connect, via conductive wires, the Input Port(s) of the IC to an extra pin(s) for Pin Package or an extra connecting pad(s) for Surface Mount Device (SMD) packaging in order to receive external input signal which can be trigger, on/off or encoded signal, and/or to connect the Input Port(s) of the IC directly to the PD, PT, LS, RS, PI or RM inside the package, and/or to connect, via conductive wires, the Output Port(s) of the IC to an extra pin(s) for Pin Package or an extra connecting pad(s) for Surface Mount Device (SMD) packaging in order to drive the other electronic components of external peripherals such as speakers or motors, etc, and/or to connect the Output Port(s) of the IC directly to the LED inside the package. As the Single or Multi Functional Integrated Circuit (IC) is bonded inside the package of the Optoelectronic Device, the conventional encapsulation for the IC and the PCB to hold the IC can be eliminated such that it can save the manufacturing and materials costs a lot.

In the description herein, numerous specific details are provided, such as examples of components and/or methods, to provide a thorough understanding of embodiments of the present invention. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

The novel features which are characteristic of the invention, as to organization and method of use, together with further objects and advantages thereof, will be better understood from the following disclosure considered in connection with the accompanying drawings in which one or more preferred embodiments of the invention are illustrated by way of example. It is to be expressly understood, however, that the drawings are for the purpose of illustration and description only and are not intended as a definition of the limits of the invention.

As used herein, the term “comprises” refers to a part or parts of a whole, but does not exclude other parts. That is, the term “comprises” is open language that requires the presence of the recited element or structure or its equivalent, but does not exclude the presence of other elements or structures. The term “comprises” has the same meaning and is interchangeable with the terms “includes” and “has”. The term set has the meaning of one or more of said element. Furthermore, any use of the term “or” as used herein is generally intended to mean “and/or” unless otherwise indicated. Combinations of components or steps will also be considered as being noted, where terminology is foreseen as rendering the ability to separate or combine is unclear.

### BRIEF DESCRIPTION OF THE DRAWINGS

Embodiments of the present disclosure are described herein with reference to the drawings, in which:

FIG. 1 is a diagram of a simple LED structure known in the prior art;

FIG. 2 is a diagram of a simple Reflective Sensor structure known in the prior art;

FIG. 3 is a diagram of a simple Photo Interrupter structure known in the prior art;

FIG. 4 is a diagram of a simple Receiver Module (RM) structure known in the prior art;

FIG. 5 is a diagram of a simple Chip On Board (COB) structure known in the prior art;

FIG. 6 is a diagram of a simple Encapsulated IC on PCB structure known in the prior art;

FIG. 7 is a diagram of a COB IC, LED and Speaker structure known in the prior art;

FIG. 8 is a diagram of a COB IC, Receiver Module and Speaker structure known in the prior art;

FIG. 9 is a diagram of an Input/Output LED structure in accordance with an embodiment of the invention;

FIG. 10 is a diagram of a multiple use, compound LED structure incorporating the LED structure of FIG. 9, in accordance with an embodiment of the current invention;

FIG. 11 is a diagram of a simplified Input/Output LED structure in accordance with another embodiment of the invention;

FIG. 12 is a diagram of a multiple use, compound LED device incorporating the LED structure of FIG. 11, in accordance with an embodiment of the current invention;

FIG. 13 is a diagram of an amplifying demodulating Input/Output Receiver Module (RM) structure in accordance with another embodiment of the invention;

FIG. 14 is a diagram of a multiple use RM device, incorporating the RM structure of FIG. 13, in accordance with an embodiment of the current invention;

FIG. 15 is a diagram of a modified multi-use Input/Output LED structure in accordance with another embodiment of the invention;

FIG. 16 is a diagram of a multi-use LED device incorporating the LED structure of FIG. 15, in accordance with an embodiment of the current invention; and

FIG. 17 is a diagram of a multi-use LED device incorporating double bonded elements, in accordance with another embodiment of the invention.

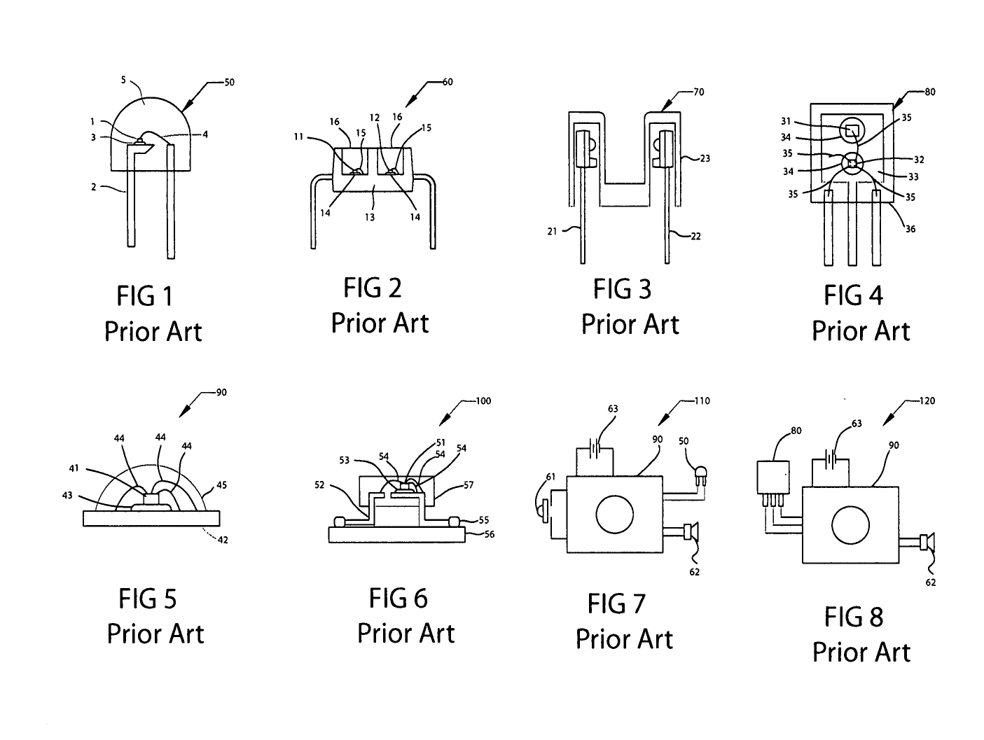

### DETAILED DESCRIPTION

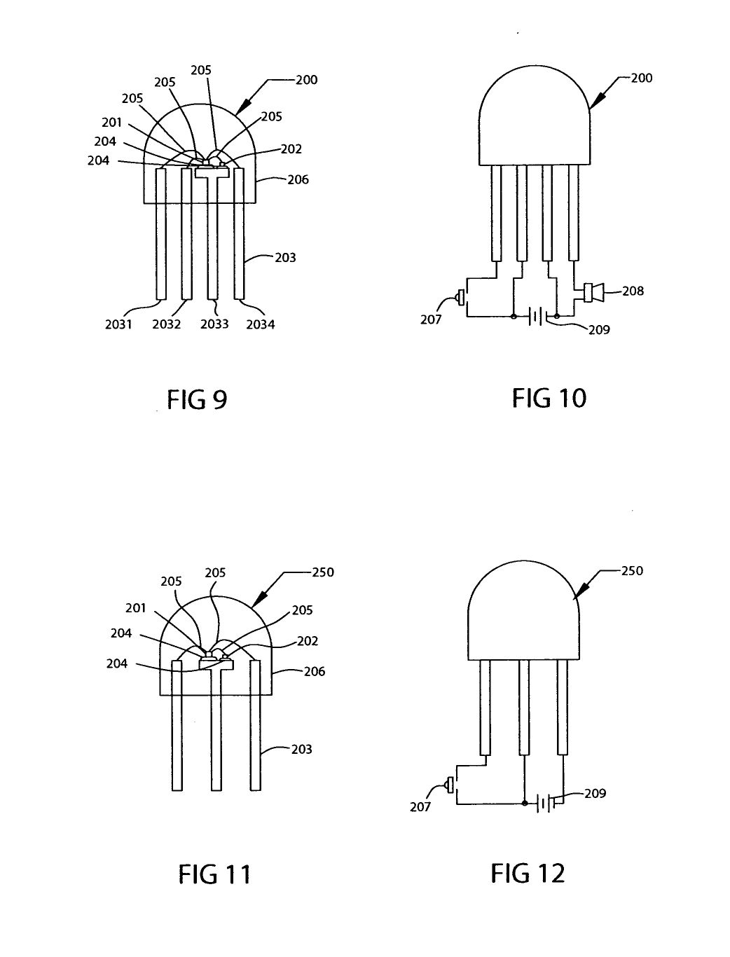

FIG. 9 illustrates a simplified structure of an Input/Output LED 200 comprising an Integrated Circuit (IC) wafer 201, LED wafer 202, a lead frame 203, bonding agents 204 and coupling wires 205. The lead frame 203 is coated with the bonding agents 204. The IC wafer 201 and LED wafer 202 are fixed via the bonding agents 204, and the coupling wires 205 are connected to the lead frame 203 to provide an electrical current flow. It is to be understood by one of ordinary skill in the art that more than one IC wafer 201, and/or more than one LED wafers 202 may be incorporated.

An epoxy resin 206, or other insulating glue, is used for encapsulating the lead frame 203 within the circuit. One or more pins 2031 form a pin packaging, or connecting pad(s) for a Surface Mount Device (SMD) package, is used to electrically connect the input port of the IC wafer 201 for receiving input signals such as trigger, on/off, or encoded signals. Additional pins 2034 may be used to connect the output port of the IC wafer 201 to external components to drive external peripheral(s) such as speakers or motors, etc. Moreover, the IC wafer 201 is built inside the Input/Output LED 200 and the conventional individual encapsulation for the IC wafer and the Printed Circuit Board (PCB) to hold the IC are eliminated.

FIG. 10 shows the compound configuration comprising an Input/Output LED 200 of FIG. 9 operatively and electrically coupled to switch 207, speaker 208 and batteries 209. As the need for encapsulation of the IC wafer and the PCB to hold the IC wafer are eliminated, the manufacturing and materials costs are significantly reduced. Input/Output LED 200 can be further simplified if the function of driving external peripherals such as speaker is not necessary.

FIG. 11 illustrates another embodiment of a LED structure 250 comprising an IC wafer 201, LED wafer 202, a lead frame 203, bonding agents 204 and coupling wires 205. The lead frame 203 is coated with the bonding agents 204. An IC wafer 201 and a LED wafer 202 are fixed via the bonding agent 204, and the coupling wires 205 are operatively connected to the lead frame 203 to provide an electrical current flow. Again, it is to be understood by one of ordinary skill in the art that more than one IC wafer 201, and/or more than one LED wafers 202 may be incorporated.

An epoxy resin 206, or other insulating glue, is used for encapsulating the lead frame 203 within the circuit. Unlike the above LED device 200, this structure employs extra pin(s) for pin packaging, or connecting pad(s) for SMD packaging, which is used to connect the input port of the IC wafer 201 external to the packaging for transmitting input signals, such as trigger, on/off, or encoded signals The extra pin(s) for Pin Package, or connecting pad(s) for SMD Package connecting to the input port(s) of the IC wafer can be one or more than one.

FIG. 12 shows the compound configuration comprising an Input/Output LED 250, switch 207, and batteries 209. Herein the need for encapsulation of the IC wafer and the PCB to hold the IC are eliminated, thus the manufacturing and materials costs are significantly reduced.

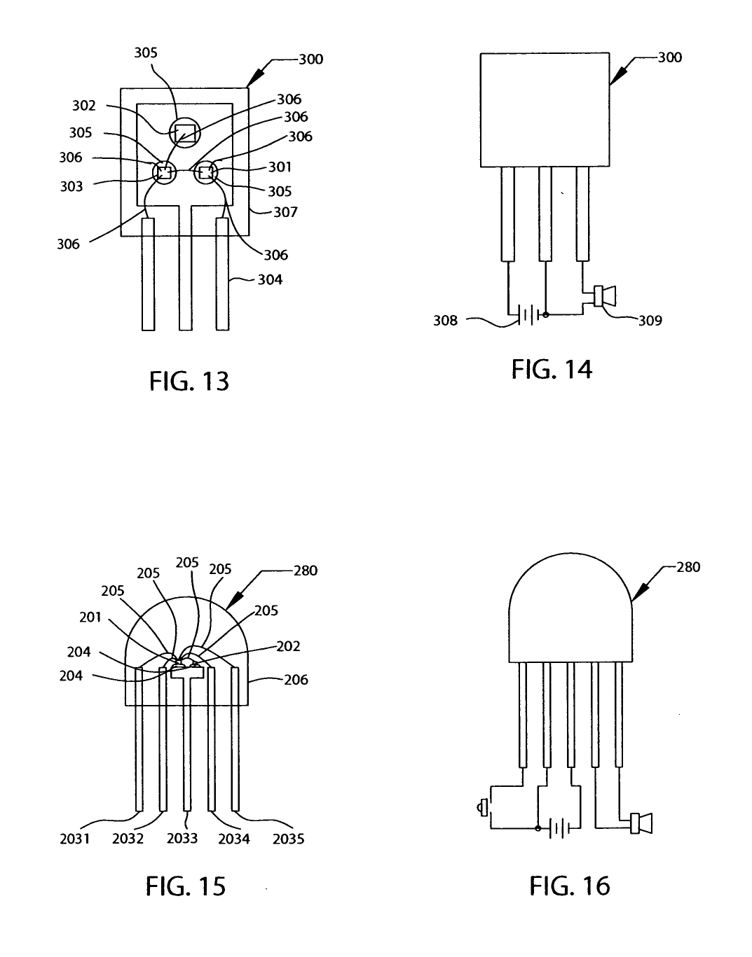

FIG. 13 illustrates another embodiment of a simplified structure of an Input/Output Receiver Module (RM) 300 comprising a Single or Multi Functional Integrated Circuit (IC) wafer 301, a photo diode wafer 302, an amplifying demodulator wafer 303, a lead frame 304, bonding agents 305 and coupling wires 306. The lead frame 304 is coated with bonding agents 305. A photo diode wafer 302, and an amplifying demodulator wafer 303 and a Single or Multi Functional Integrated Circuit (IC) wafer 301 are affixed via the bonding agents 305, and the coupling wires 306 are operatively coupled and electrically connected to the lead frame 304 to provide electrical current flow. One of ordinary skill in the art would understand that a plurality of photodiodes 302, amplifying demodulator wafers 303, and/or one or more Single or Multi Functional Integrated Circuit (IC) wafers 301 may be incorporated herein.

An epoxy resin 307, or other insulation glue, is used for encapsulating the lead frame 304 within the circuit. This structure is used to connect the output port of the amplifying demodulator wafer 303 directly to the input port of the Single or Multi Functional Integrated Circuit (IC) wafer 301, and to connect the output port of the IC wafer 301 to the lead frame 304 in order to drive any external peripheral(s), such as speakers, or motors, etc.

FIG. 14 illustrates a compound configuration comprising an Input/Output RM 300, operatively coupled to batteries 308 and a speaker 309. As the need for encapsulation of the IC wafer and the PCB to hold the IC are eliminated, the manufacturing and materials costs are again significantly reduced.

The Input/Output LED 200 can be further modified if the driving mode of the Single or Multi Functional Integrated Circuit (IC) is used for Dual Phase Output (DPO) or Pulse Width Modulation (PWM), such as being coupled to external peripherals, e.g., speakers for example. FIG. 15 illustrates another such structure 280 which has two extra pin(s) 2034 and 2035 for pin packaging or connecting pad(s) for SMD packaging to connect the output ports of the IC wafer, the driving mode of which is DPO or PWM, externally to drive external peripheral(s), such as speakers. The extra pin(s) can be one, or a plurality thereof. FIG. 16 illustrates a compound configuration comprising an Input/Output LED 280 as above, operatively coupled to a switch, batteries and a speaker.

### Double Bonding Agents

For some Single or Multi Functional Integrated Circuits (IC), the substrate of the ICs should be isolated, or connected to the ground, or negative terminal of power supply. Therefore, the lead frame under the substrate of the IC should be connected to ground or negative terminal of power supply or isolated too. However, for some circuit configurations, the lead frame under the substrate of the IC needs to be connected to Vcc (Voltage Channel Connection) or the positive terminal of the power supply such that insulating glue may be used as a bonding agent to isolate the IC from the lead frame.

However, in some instances, the size of the IC is larger. If using insulating glue, during the bonding process, the IC cannot be firmly fixed on the lead frame, and as a result the IC's position may be deviated. If using conductive glue, although it can firmly fix the position of the IC, the lead frame should be connected to ground or negative terminal of power supply and hence some circuit configurations cannot be used. The instant invention addresses this problem as discussed further below.

In consideration for the manufacturing process steps of double bonding, first, coat the insulation glue on the lead frame. Second, dry via high temperature (e.g., baking). Third, coat the conductive glue on the surface of the insulation glue. Finally, bond the IC on the surface of the conductive glue. The insulation glue can isolate the IC from the lead frame so the lead frame can be connected to Vcc or positive terminal of power supply and hence any kind of circuit configurations can be applied. And the conductive glue can firmly fix the position of the IC.

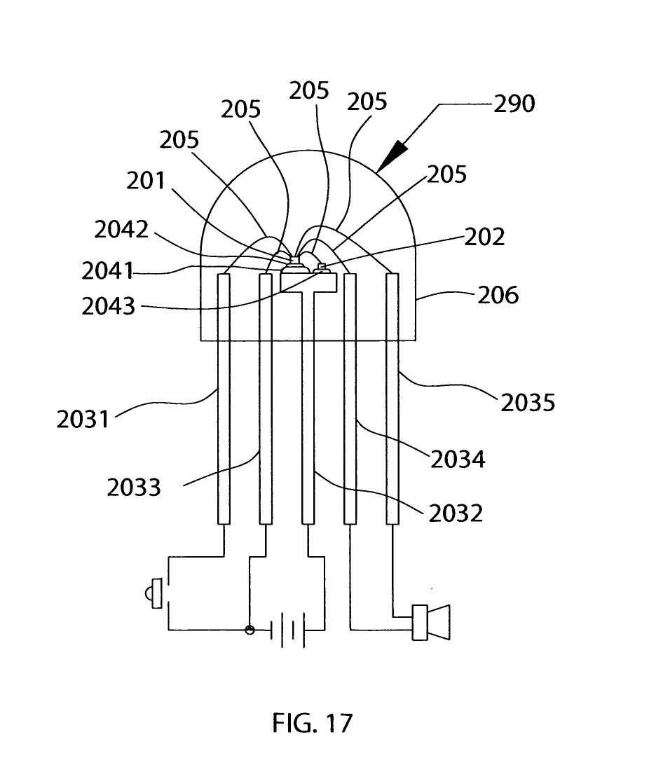

FIG. 17 illustrates another embodiment including the double bonded structure as shown by the Input Output LED device 290, which comprises an IC wafer 201, LED wafer 202, a lead frame 2031 to 2035, insulation glue of bonding agents 2041, conductive glue of bonding agents 2042 and 2043, and coupling wires 205. Part of the lead frame 2032, such as an upper surface portion, is coated with the insulation glue of bonding agents 2041. The insulation glue of bonding agents 2041 is baked at a high temperature for drying. Next, the surface of the insulation glue is coated with the conductive glue of bonding agents 2042 such as, for example silver epoxy. The upper portion of the lead frame 2032 is coated with the conductive glue of bonding agents 2043. An IC wafer 201 is affixed via the conductive glue of bonding agents 2042, using insulation glue of bonding agents 2041 on the lead frame 2032, and a LED wafer 202 is affixed to the conductive glue of bonding agents 2043 on the lead frame 2032, and the coupling wires 205 are electrically coupled to the lead frame 2031 to 2035 to provide an electrical current flow. It is to be understood by one of ordinary skill in the art that a plurality of wafers may be employed, without departing from the scope of the invention. An epoxy resin 206, or other insulation glue, is used for encapsulating the lead frame 2031 to 2035 within the circuit.

This invention can apply to all kind of optoelectronic devices including LED's (Light Emitting Diode), PD's (Photo Diode), PT's (Photo Transistor), LS's (Light Sensor), RS's (Reflective Sensor), PI's (Photo Interrupter) and RM's (Receiver Module). The optoelectronic devices may be a conventional pin package having three or more supporting legs and/or SMD (Surface Mount Device) package having no supporting legs but having three or more connecting pads.

It is to be appreciated that one or more of the elements depicted in the drawings/figures can also be implemented in a more separated or integrated manner, or even removed or rendered as inoperable in certain cases, as is useful in accordance with a particular application. It is also within the spirit and scope of the present invention to implement a program or code that can be stored in a machine-readable medium to permit a computer to perform or assist with any of the methods and procedures for manufacturing the apparatus described herein.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention not be limited to the particular terms used and/or to the particular embodiment disclosed as the best mode contemplated for carrying out this invention, but that the invention will include any and all embodiments and equivalents falling within the scope of the instant disclosure.

For example, the LED wafer may be bonded by a single conductive wire, or multiple wires. A product may have one or several wafer, depending on the features needed. The set of lead frames may have two or more supporting legs, or none at all (surface mounted device). Moreover, a pigment, a diffusing agent or fluorescent phosphor powder may be added into the LED or the epoxy layer. The pigment makes the LED or the epoxy layer colorful; the diffusing agent allows the entirety of the LED or the epoxy layer to emit light; and the fluorescent phosphor powder is capable of changing the wavelength and therefore changing the color of the emitted light. The light-emitting intensity and the color of the emitted light is determined by the wafer, however the wafer does not make any color, it is the fluorescent phosphor powder that is added that can change and modify the color. Moreover, a color filtering pigment may be added into the PD, PT, LS, RS, PI or RM in order to filter the visible light or to filter the invisible light.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

What is claimed is:

1. A multi-functional optoelectronic apparatus, comprising:
at least one optoelectronic device;
at least one integrated circuit (IC) wafer;
said optoelectronic device and IC wafer operatively coupled to one another by a set of conductive lead wires,
an insulating, transparent epoxy housing fully encapsulating said optoelectronic device and IC wafer;
a set of conductive lead frames, and wherein said optoelectronic device and said IC wafer are operatively and electrically coupled to said conductive lead frames,
and said insulating, transparent epoxy housing partially encapsulating said set of conductive lead frames.

2. The multi-functional optoelectronic apparatus of claim 1,
wherein said set of conductive lead frames are operatively coupled to at least one external peripheral device.

3. The multi-functional optoelectronic apparatus of claim 2, further comprising an optoelectronic device selected from the group consisting of light emitting diodes, photodiodes, phototransistors, light sensors, reflective sensors, photo interrupters, and receiver modules.

4. The multi-functional optoelectronic apparatus of claim 3, wherein said at least one external peripheral device is a power source.

5. The multi-functional optoelectronic apparatus of claim 4, wherein said at least one external peripheral device is a switch.

6. The multi-functional optoelectronic apparatus of claim 4, wherein said at least one external peripheral device is a speaker.

7. The multi-functional optoelectronic apparatus of claim 6, further comprising an amplifying demodulating wafer.

8. A multi-functional optoelectronic apparatus, comprising:
an integrated circuit (IC) wafer;
a first optoelectronic device;
a second optoelectronic device;
said IC wafer, first and second optoelectronic devices operatively and electrically coupled to one another by a set of conductive lead wires,
an insulating, transparent epoxy housing fully encapsulating said IC wafer, first and second optoelectronic devices;
a set of conductive lead frames, and wherein said IC wafer, first and second optoelectronic devices are operatively and electrically coupled to said conductive lead frames,
and said insulating, transparent epoxy housing partially encapsulating said set of conductive lead frames.

9. The multi-functional optoelectronic apparatus of claim 8 wherein said first optoelectronic device is a light emitting diode (LED) device.

10. The multi-functional optoelectronic apparatus of claim 9 wherein said second optoelectronic device is a device selected from the group consisting of photodiodes, phototransistors, light sensors, reflective sensors, photo interrupters, and receiver modules.

11. The multi-functional optoelectronic apparatus of claim 10,
wherein said set of conductive lead frames are operatively coupled to the external peripheral devices.

12. The multi-functional optoelectronic apparatus of claim 11, further comprising an amplifying demodulating wafer.

13. The multi-functional optoelectronic apparatus of claim 12, wherein said at least one external peripheral device is a power source.

14. The multi-functional optoelectronic apparatus of claim 13, wherein said at least one external peripheral device is a switch.

15. The multi-functional optoelectronic apparatus of claim 14, wherein said at least one external peripheral device is a speaker.

16. The multi-functional optoelectronic apparatus of claim 15, further comprising a double bonding agent layer having an electrically conductive glue layer, and an electrically insulating glue layer operatively coupled together such that said IC wafer is affixed to said conductive glue layer, and said conductive glue layer is affixed to said insulating glue layer.
